(19) United States
(12) Patent Application Publication
(10) Pub. No.: US 2018/0246374 A1
(43) Pub. Date: Aug. 30, 2018

(54) REFLECTIVE ARRAY SUBSTRATE, MANUFACTURING METHOD THEREOF, AND DISPLAY DEVICE

(71) Applicant: BOE TECHNOLOGY GROUP CO., LTD., Beijing (CN)

(72) Inventors: Shuilang DONG, Beijing (CN); Xinhong LU, Beijing (CN); Liwen DONG, Beijing (CN)

(21) Appl. No.: 15/788,940

(22) Filed: Oct. 20, 2017

(30) Foreign Application Priority Data
Feb. 28, 2017 (CN) 201710113747.1

(51) Int. Cl. G02F 1/1335; H01L 27/12; G02F 1/1368

(52) U.S. Cl. CPC G02F 1/133553; H01L 27/1218; H01L 27/1262; G02F 2001/133357; G02F 2001/133567; G02F 1/133514; G02F 2201/50; G02F 1/1368

(57) ABSTRACT

Embodiments of the present disclosure provide a reflective array substrate, a manufacturing method thereof, and a display device. The reflective array substrate includes a support substrate, an array structure layer and a light reflection layer, wherein the array structure layer is arranged on a first surface of the support substrate, the light reflection layer is arranged on a second surface of the support substrate, and the first surface and the second surface face away from each other.

### CROSS REFERENCE

This application is based upon and claims priority to Chinese Patent Application No. 201710113747.1, filed on Feb. 28, 2017, the entire contents thereof are incorporated herein by reference.

### TECHNICAL FIELD

The present disclosure relates to the field of display technologies, and particularly to a reflective array substrate, a manufacturing method thereof, and a display device.

### BACKGROUND

Liquid crystal display (LCD) may be divided into transmissive LCD, reflective LCD and semi-reflective and semi-transmissive LCD according to light collecting modes. The reflective LCD use reflection of ambient light (such as sunlight) to display. Compared with backlight transmissive LCD, the reflective LCD have no backlight, and thus being high in contrast ratio, low in power consumption, thin in size and light in weight. Furthermore, use of natural light for reflective display is advantageous to visual protection. Therefore, the reflective LCD is increasingly used in portable electronic terminals such as mobile phones, notebook computers, digital cameras, and personal digital assistants, etc.

Major structures of an existing reflective LCD include an array (thin film transistor, TFT) substrate and a color filter (CF) substrate assembled with each other. Liquid crystal (LC) is filled between the array substrate and the color filter substrate. The array substrate is provided with a light reflection structure for reflecting light rays from outside. At present, in the prior art, a light reflection structure utilizes a pixel electrode as a light reflection layer. In view of a fact that planarization of the light reflection layer is of vital importance to a reflectivity, therefore, it is necessary to perform planarization treatment before the light reflection layer is fabricated. However, over-thick planarization layer not only causes greater difficulty to form a via hole, but also reduces the reliability of connecting the pixel electrode to a drain electrode through the via hole. In another light reflection structure of the prior art, a light reflection layer is arranged beneath an array structure layer. That is, the light reflection layer is first manufactured on a support substrate, and then the array structure layer is formed on the light reflection layer. However, this structure increases the difficulty of manufacturing the array structure layer. The reason is that high molecular imprinting materials used in the light reflection layer are lower in bearing temperature and higher in thickness, which requires the subsequent processes of the array structure layer to be proceeded at low temperature. Therefore, how to reduce the difficulty of the manufacturing process of a reflective LCD is a technical problem to be solved urgently in the field.

### SUMMARY

A technical problem to be solved by embodiments of the present disclosure is to provide a reflective array substrate, a manufacturing method thereof and a display device to solve the technical problem that an existing structure is difficult in manufacturing process.

To solve the above technical problem, an aspect of the present disclosure provides a reflective array substrate, including a support substrate, an array structure layer and a light reflection layer, wherein the array structure layer is arranged on a first surface of the support substrate, the light reflection layer is arranged on a second surface of the support substrate, and the first surface and the second surface face away from each other.

Another aspect of the present disclosure provides a display device, including an array substrate and a color filter substrate assembled with each other. The array substrate includes a support substrate, an array structure layer and a light reflection layer, wherein the array structure layer is arranged on a first surface of the support substrate, the light reflection layer is arranged on a second surface of the support substrate, and the first surface and the second surface face away from each other.

Another aspect of the present disclosure provides a manufacturing method of a reflective array substrate, including:

manufacturing an array structure layer on a first surface of a support substrate; and

manufacturing a light reflection layer on a second surface of the support substrate, wherein the first surface and the second surface face away from each other.

### BRIEF DESCRIPTION OF THE DRAWINGS

The accompanying drawings are provided for further understanding the technical solutions of the present disclosure and constitute a part of the specification, and, together with the embodiments of the present disclosure, are provided to interpret the technical solutions of the present disclosure, rather than limiting the technical solutions of the present disclosure. Shapes and sizes of parts in the accompanying drawings do not reflect true scale thereof, and the objective is merely to schematically illustrate contents of the present disclosure.

FIG. 1 is a schematic structural diagram of a reflective LCD according to an embodiment of the present disclosure;

FIG. 2 is a schematic structural diagram of a reflective array substrate according to a first embodiment of the present disclosure;

FIG. 3 is an enlarged view of Region A in FIG. 2;

FIG. 4 is a flowchart of a manufacturing method according to the first embodiment of the present disclosure; and

FIG. 5 is a schematic structural diagram of a reflective array substrate according to a second embodiment of the present disclosure.

Reference numbers in the attached drawings:

| | | |
|---|---|---|
| 1-array substrate; | 2-color filter substrate; | 3-liquid crystal; |
| 10, 20-support substrate; | 11-array structure layer; | 12-light reflection layer; |
| 111-gate electrode; | 112-gate insulation layer; | 113-active layer; |
| 114-source/drain electrodes; | 115-passivation layer; | 116-pixel electrode; |
| 117-planarization layer; | 121-configuring layer; | 122-reflecting layer; |
| 123-protective layer; | 21-color filter structure layer. | |

### DETAILED DESCRIPTION

In the following, specific implementations of the present disclosure are further described in detail with reference to the accompanying drawings and embodiments. The following embodiments are intended to describe the present disclosure but are not intended to limit the scope of the present disclosure. It is to be noted that the embodiments of this application and the features in the embodiments may be arbitrarily combined with each other in the case of no conflict.

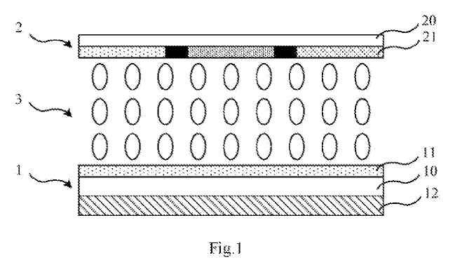

In view of the technical problem that an existing reflective LCD is difficult in manufacturing process, an embodiment of the present disclosure provides a reflective LCD. FIG. 1 is a schematic structural diagram of the reflective LCD according to the embodiment of the present disclosure. As shown in FIG. 1, a major structure of the reflective LCD according to the embodiment of the present disclosure includes an array substrate 1 and a color filter substrate 2 assembled with each other. A liquid crystal 3 is filled between the array substrate and the color filter substrate. The color filter substrate 2 includes a support substrate 20 and a color filter structure layer 21 formed on the support substrate 20. The array substrate 1 includes a support substrate 10, an array structure layer 11 and a light reflection layer 12. The array structure layer 11 is arranged on a surface (hereinafter to be referred as “front surface”) of the support substrate 10 facing toward the color filter substrate 2. The light reflection layer 12 is arranged on a surface (hereinafter to be referred as “back surface”) of the support substrate 10 facing away from the array structure layer 11, and the light reflection layer 12 is formed after forming the array structure layer 11. The light reflection layer 12 is configured to reflect ambient light, so that the ambient light is used to provide backlight for the reflective LCD. According to the embodiment of the present disclosure, the light reflection layer is arranged on the back surface of the support substrate, and the light reflection layer is formed after forming the array structure layer. In this way, the difficulty of the manufacturing process of the reflective LCD is effectively reduced.

LCD display mode may include a twisted nematic (TN) display mode, an in plane switching (IPS) display mode, a fringe field switching (FFS) display mode, and an advanced super dimension switch (ADS) display mode, etc. The technical solution of the embodiment of the present disclosure is described in the following taking a reflective LCD having the TN display mode as an example. However, application of the embodiment of the present disclosure is not limited thereto, and the present disclosure also may be applied to reflective LCD having other display modes.

### The First Embodiment

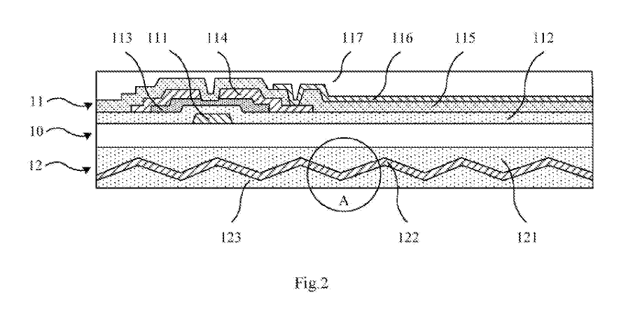

FIG. 2 is a schematic structural diagram of a reflective array substrate according to the first embodiment of the present disclosure. As shown in FIG. 2, the reflective array substrate of this embodiment includes a support substrate 10, an array structure layer 11 arranged on the front surface of the support substrate 10 and a light reflection layer 12 arranged on the back surface (namely, a side surface of the support substrate 10 facing away from the array structure layer 11) of the support substrate 10. In this embodiment, the “front surface” refers to a surface of the reflective LCD facing toward a viewer when in use, the ambient light enters from the front surface, and the “back surface” refers to a surface facing away from the viewer. Specifically, the light reflection layer 12 includes a configuring layer 121, a reflecting layer 122 and a protective layer 123. The configuring layer 121 is arranged on the back surface of the support substrate 10 and forms a light reflection structure. The reflecting layer 122 is arranged on a surface of the configuring layer 121 away from the support substrate 10. The protective layer 123 is arranged on a surface of the reflecting layer 122 away from the support substrate 10. The array structure layer 11 includes a gate electrode 111, a gate insulation layer 112, an active layer 113, a source/drain electrode 114, a passivation layer 115, a pixel electrode 116 and a planarization layer 117 sequentially arranged on the support substrate 10. The pixel electrode is connected to the source electrode or the drain electrode through a via hole provided on the passivation layer. The gate electrode, the active layer and the source/drain electrode form a thin film transistor.

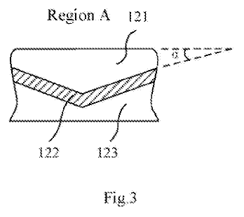

FIG. 3 is an enlarged view of Region A in FIG. 2. As shown in FIG. 3, in the reflective array substrate provided by this embodiment, the reflecting layer 122 includes a plurality of regularly-arranged reflection structures, and each of the reflection structures is a convex. In this embodiment, the convex is a trigone (shaped like a pyramid), the cross section thereof is a triangle whose base angle α ranges from 5 degrees to 30 degrees. That is, an included angle between a side face of the trigone and a plane where the support substrate is ranges from 5 degrees to 30 degrees. Four reflecting surfaces at the angle of a relative to the back surface of the support substrate are formed. Each reflecting surface of the trigone reflects incident light rays of the ambient light (for example, sunlight), and regulates the direction of the reflected light rays to a pixel region. Therefore, the reflecting layer in this embodiment may effectively improve the utilization factor of the ambient light, thereby guaranteeing the display brightness of the reflective LCD. In this embodiment, the trigone (a convex) refers to a outwardly projecting shape formed taking the back surface of the support substrate as a benchmark. In substance, the trigone is a triangular shell whose internal surface serves as a reflecting surface for reflecting the ambient light. When in specific implementation, the reflecting layer 122 adopts a metallic material having a higher reflectivity, for example, metals such as Al, Cu, Mo, Ti, Ag or the like and alloys of these metals such as AlNd. The reflecting layer 122 has a thickness of 100˜1,000 nm. Therefore, the reflection efficiency is increased. The configuring layer adopts a nanoimprinting material which adopts an organosilicon material having a high transmittance such as epoxy and so on. The configuring layer also may adopt other suitable materials. The protective layer may adopt resin or SiNx. To improve the uniformity of reflected light rays, the convex is arranged axisymmetrically, and the base angle α of the trigone may be set up according to parameters such as the size of the pixel region or the thickness of the array structure layer based on actual conditions. Optionally, the base angle α of the trigone ranges from 10 degrees to 15 degrees to maximize the utilization factor of the ambient light. When in specific implementation, the trigone also may be arranged non-axisymmetrically. The base angle of the reflecting surface at a side of the trigone is larger than that of the reflecting surface at another side of the trigone, such that the reflecting surface formed at a side is larger than that formed at another side, which may regulate the reflected light rays to the corresponding to pixel region to the utmost extent. Further, adjacent trigones may be spaced by a preset distance, or may be arranged continuously (as shown in FIG. 2, a spacing distance=0).

The reflective array substrate of this embodiment includes a plurality of gate lines and a plurality of data lines formed on the support substrate. Each row of the gate lines vertically intersect with each column of the data lines to form, on the support substrate, a plurality of array-arranged pixel regions. Each pixel region is provided with a thin film transistor and a pixel electrode. The gate line is used for providing a scanning signal for the corresponding thin film transistor, and the thin film transistor is turned on in response to the scanning signal of the gate line, so that a voltage from the data line is applied to the pixel electrode.

The technical solution of this embodiment is further described below through a manufacturing process of the array substrate.

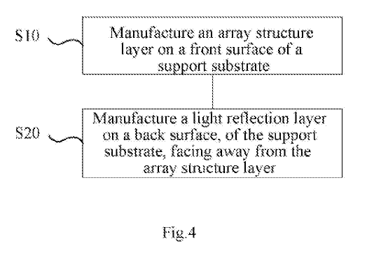

FIG. 4 is a flowchart of a manufacturing method according to a first embodiment of the present disclosure. As shown in FIG. 4, the manufacturing method of the array substrate of this embodiment includes following steps:

S10: manufacturing an array structure layer on a front surface of a support substrate; and

S20: manufacturing a light reflection layer on a back surface, of the support substrate, facing away from the array structure layer.

In this embodiment, an array structure layer is first manufactured on a side surface (front surface) of the support substrate using a patterning process, and after the array structure layer is finished, a light reflection layer is manufactured on another side surface (namely, the back surface, of the support substrate, facing away from the array structure layer) of the support substrate. As an existing mature manufacturing process, the “patterning process” as mentioned in this embodiment includes depositing a film layer, coating a photoresist, mask exposing, developing, etching, removing the photoresist and so on. Film layer materials, processes and parameters or the like are known. Manufacturing the array structure layer includes forming a thin film transistor, gate lines and data lines, a gate insulation layer, a passivation layer and a pixel electrode on the support substrate, and may further include forming other film layers such as a planarization layer, which may be learned by those skilled in the art according to common general knowledge and the prior art, and is not specifically limited herein.

In this embodiment, manufacturing a light reflection layer includes following steps:

S201: manufacturing a configuring layer on the back surface, of the support substrate, facing away from the array structure layer;

S202: manufacturing a reflecting layer on the configuring layer; and

S203: manufacturing a protective layer on the reflecting layer.

In this embodiment, after the array structure layer is manufactured on the front surface of the support substrate, the light reflection layer is formed on the back surface of the support substrate. In Step S201, a layer of nanoimprinting thin film (the thickness is 5˜10 μm) is coated on the back surface of the support substrate, a plurality of regularly-arranged convex patterns are printed on the surface of the nanoimprinting thin film using a nanoimprinting process, and a configuring layer is formed after curing treatment. In Step S202, a layer of metal thin film (the thickness is 100˜1,000 nm) is deposited on the formed configuring layer, so that the deposited metal thin film has a morphology the same as the surface of the configuring layer, and a reflecting layer where a plurality of convexes are regularly arranged is formed. In Step S203, a layer of resin material (the thickness is 5˜10 μm) is coated on the formed reflecting layer, and a protective layer is formed after curing treatment. The protective layer also serves as a planarization layer so that the back surface of the support substrate is planarized. The metal thin film may adopt metallic materials having a high reflectivity, for example, metals such as Al, Cu, Mo, Ti, Ag and so on and alloys of these metals such as AlNd. The nanoimprinting material may adopt an organosilicon material having a high transmittance, such as epoxy and so on. The nanoimprinting material also may adopt other suitable materials. The protective layer may adopt resin or SiNx, etc. Curing temperature and time of the configuring layer and the protective layer depend on actual needs, about 200˜250° C. Deposition may be performed by adopting known processes such as sputtering, evaporation, chemical vapor deposition and so on. Coating and imprinting may be performed by adopting known coating processes and imprinting processes, which are not specifically limited herein.

According to the reflective array substrate provided by this embodiment, the light reflection layer is arranged on the back surface of the support substrate, and the light reflection layer is formed after forming the array structure layer. It is unnecessary to greatly change the existing manufacturing process. Therefore, the difficulty of the manufacturing process of the reflective LCD is reduced, and the light reflection effect may be effectively guaranteed.

### The Second Embodiment

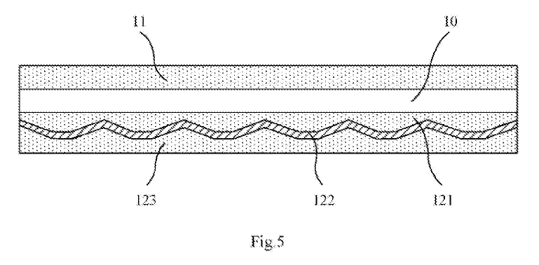

The major structure of the reflective array substrate provided by this embodiment is the same as that provided by the first embodiment, including a support substrate 10, an array structure layer 11 arranged on the front surface of the support substrate 10 and a light reflection layer 12 arranged on the back surface of the support substrate 10. The light reflection layer 12 includes a configuring layer 121, a reflecting layer 122 and a protective layer 123. The reflecting layer 122 includes a plurality of regularly-arranged reflection structures, and each of the reflection structures is a convex. FIG. 5 is a schematic structural diagram of a reflective array substrate according to a second embodiment of the present disclosure. As shown in FIG. 5, different from the first embodiment, the convex in this embodiment is a trapezoid body, and the cross section thereof is an isosceles trapezoid whose base angle α ranges from 5 degrees to 30 degrees. That is, an included angle between a side face of the trapezoid body and a plane where the support substrate is ranges from 5 degrees to 30 degrees. Five reflecting surfaces are formed, including one reflecting surface in parallel with the back surface of the support substrate and four reflecting surfaces at the angle of a relative to the back surface of the support substrate. Optionally, the base angle α of the isosceles trapezoid ranges from 10 degrees to 15 degrees. When in specific implementation, the convex also may be a cone. In this embodiment, a plurality of reflecting surfaces are provided, which not only may effectively regulate the reflected light rays to the corresponding pixel region and improve the utilization factor of ambient light, but also may reduce the difficulty of the manufacturing process of the light reflection layer. In this embodiment, materials and manufacturing methods of the array structure layer, the configuring layer, the reflecting layer and the protective layer are the same as those in the first embodiment, and thus their detailed descriptions are omitted herein.

### The Third Embodiment

The major structure of the reflective array substrate provided by this embodiment is the same as that provided by the first embodiment, including a support substrate 10, an array structure layer 11 arranged on the front surface of the support substrate 10 and a light reflection layer 12 arranged on the back surface of the support substrate 10. The light reflection layer 12 includes a configuring layer 121, a reflecting layer 122 and a protective layer 123. The reflecting layer 122 includes a plurality of regularly-arranged reflection structures, and each of the reflection structures is a convex. Different from the first embodiment, the convex in this embodiment is an arc-shaped body, and the cross section thereof is an arc whose base angle α ranges from 5 degrees to 30 degrees. That is, an included angle between a side face of the arc-shaped body and a plane where the support substrate is ranges from 5 degrees to 30 degrees. Continuous reflecting surfaces are formed. Optionally, the base angle α of the arc ranges from 10 degrees to 15 degrees. In this embodiment, continuous reflecting surfaces are provided, which not only may effectively regulate the reflected light rays to the corresponding pixel region and improve the utilization factor of ambient light, but also may reduce the difficulty of the manufacturing process of the reflecting layer. In this embodiment, materials and manufacturing methods of the array structure layer, the configuring layer, the reflecting layer and the protective layer are the same as those in the first embodiment, and thus their detailed descriptions are omitted herein.

### The Fourth Embodiment

On the basis of the technical solution of the foregoing embodiment, the convex of this embodiment is a composite structure of different shapes, namely, the cross sections of the convex are different in shape. For example, the convex is a composite structure of a trigone and a trapezoid body. That is, the cross sections of the convex respectively are a triangle and a trapezoid, and arranged in a spaced way, namely, a trapezoid body is between two trigones, a trigone is between two trapezoid bodies. For another example, the convex is a composite structure of a trigone, a trapezoid body and an arc-shaped body. That is, the cross sections of the convex respectively are a triangle, a trapezoid and an arc, and arranged in a preset way.

### The Fifth Embodiment

Based on the same inventive concept, an embodiment of the present disclosure also provides a reflective LCD, which includes the reflective array substrate according to any one of the preceding embodiments, and a color filter substrate that is assembled with respect to the reflective array substrate. The reflective LCD may be any product or component having a display function, such as a mobile phone, a notebook computer, a digital camera, a navigation device, a personal digital assistant and so on. The repetition is not unnecessarily described any more.

In conclusion, according to the reflective array substrate, a manufacturing method thereof, and a display device provided by the embodiments of the present disclosure, the light reflection layer is arranged on the back surface of the support substrate, and the light reflection layer is formed after forming the array structure layer. Compared with the prior art where a pixel electrode is used as the light reflection layer, the present disclosure avoids forming a via hole on an over-thick planarization layer. Compared with the prior art where a light reflection layer is arranged beneath the array structure layer, the present disclosure avoids low temperature requirements for the array structure layer. Therefore, the embodiments of the present disclosure reduce the difficulty of the manufacturing process of the reflective LCD, and it is unnecessary to greatly change the existing manufacturing process.

Of course, any product or method for implementing the present disclosure does not necessarily have all the foregoing advantages simultaneously. Additional features and advantages of the present disclosure will be set forth in the embodiments of the description which follows, and in part will be apparent from the embodiments of the description, or may be learned by implementing the present disclosure. The objectives and other advantages of the present disclosure may be implemented and obtained by structures particularly indicated in the specification, the claims and the accompanying drawings.

In the description of the embodiments of the present disclosure, it is to be noted that the orientations or positions represented by the terms of “middle”, “up”, “down”, “front”, “back”, “vertical”, “horizontal”, “top”, “bottom”, “in”, “out”, and the like are based on the orientations or positions as shown in the accompanying figures, they are merely for ease of a description of the present disclosure and a simplified description instead of being intended to indicate or imply the device or element to have a special orientation or to be configured and operated in a special orientation. Thus, they cannot be understood as limiting of the present disclosure.

In the description of the embodiments of the present disclosure, it is to be noted that unless specified or limited otherwise, terms “installation”, “connecting” or “connection” should be understood in a broad sense, which may be, for example, a fixed connection, a detachable connection or integrated connection, a mechanical connection or an electrical connection, a direct connection or indirect connection by means of an intermediary, or internal communication between two components. For those of ordinary skill in the art, specific meanings of the above terms in the present disclosure may be understood based on specific circumstances.

The above are embodiments disclosed by the present disclosure. However, the described contents are merely embodiments adopted for better understanding the present disclosure rather than limiting the present disclosure. Any person skilled in the art can make any modification and variation to the implementing forms or details without departing from the spirit and scope of the present disclosure. However, the patent protection scope of the present disclosure should still be subjected to the scope defined in the appended claims.

What is claimed is:

1. A reflective array substrate, comprising a support substrate, an array structure layer and a light reflection layer, wherein the array structure layer is arranged on a first surface of the support substrate, the light reflection layer is arranged on a second surface of the support substrate, and the first surface and the second surface face away from each other.

2. The reflective array substrate according to claim 1, wherein the light reflection layer comprises a configuring layer, a reflecting layer and a protective layer; the configuring layer is arranged on the second surface of the support substrate and is configured to form a light reflection structure; the reflecting layer is arranged on a surface, of the configuring layer, away from the support substrate; and the protective layer is arranged on a surface, of the reflecting layer, away from the support substrate.

3. The reflective array substrate according to claim 2, wherein the reflecting layer comprises a plurality of regularly-arranged reflection structures, and each of the reflection structures is a convex.

4. The reflective array substrate according to claim 3, wherein the convex comprises a trigone, a trapezoid body and an arc-shaped body, or the convex comprises a trigone, a trapezoid body or an arc-shaped body.

5. The reflective array substrate according to claim 4, wherein an included angle between a side face of the trigon, the trapezoid body or the arc-shaped body and a plane where the support substrate is ranges from 5 degrees to 30 degrees.

6. The reflective array substrate according to claim 2, wherein the configuring layer has a thickness of 5˜10 μm, the reflecting layer has a thickness of 100˜1,000 nm, and the protective layer has a thickness of 5˜10 μm.

7. A display device, comprising an array substrate and a color filter substrate assembled with each other, the array substrate comprising:
a support substrate, an array structure layer and a light reflection layer, wherein the array structure layer is arranged on a first surface of the support substrate, the light reflection layer is arranged on a second surface of the support substrate, and the first surface and the second surface face away from each other.

8. The display device according to claim 7, wherein the light reflection layer comprises a configuring layer, a reflecting layer and a protective layer; the configuring layer is arranged on the second surface of the support substrate and is configured to form a light reflection structure; the reflecting layer is arranged on a surface, of the configuring layer, away from the support substrate; and the protective layer is arranged on a surface, of the reflecting layer, away from the support substrate.

9. The display device according to claim 8, wherein the reflecting layer comprises a plurality of regularly-arranged reflection structures, and each of the reflection structures is a convex.

10. The display device according to claim 9, wherein the convex comprises a trigone, a trapezoid body and an arc-shaped body, or the convex comprises a trigone, a trapezoid body or an arc-shaped body.

11. The reflective array substrate according to claim 10, wherein an included angle between a side face of the trigone, the trapezoid body or the arc-shaped body and a plane where the support substrate is ranges from 5 degrees to 30 degrees.

12. The reflective array substrate according to claim 8, wherein the configuring layer has a thickness of 5˜10 μm, the reflecting layer has a thickness of 100˜1,000 nm, and the protective layer has a thickness of 5˜10 μm.

13. A manufacturing method of a reflective array substrate, comprising:
manufacturing an array structure layer on a first surface of a support substrate; and
manufacturing a light reflection layer on a second surface of the support substrate, wherein the first surface and the second surface face away from each other.

14. The manufacturing method according to claim 13, wherein the step of manufacturing a light reflection layer on a second surface of the support substrate comprises:
manufacturing a configuring layer on the second surface of the support substrate;
manufacturing a reflecting layer on a surface, of the configuring layer, away from the support substrate; and
manufacturing a protective layer on a surface, of the reflecting layer, away from the support substrate.

15. The manufacturing method according to claim 14, wherein the reflecting layer comprises a plurality of regularly-arranged reflection structures, and each of the reflection structures comprises a trigone, a trapezoid body and an arc-shaped body, or each of the reflection structures comprises a trigone, a trapezoid body or an arc-shaped body.

16. The manufacturing method according to claim 15, wherein an included angle between a side face of the trigone, the trapezoid body or the arc-shaped body and a plane where the support substrate is ranges from 5 degrees to 30 degrees.

17. The manufacturing method according to claim 15, wherein the configuring layer has a thickness of 5˜10 μm, the reflecting layer has a thickness of 100˜1,000 nm, and the protective layer has a thickness of 5˜10 μm.
